(19) United States
(12) Patent Application Publication
(10) Pub. No.: US 2015/0131071 A1
(43) Pub. Date: May 14, 2015

(54) SEMICONDUCTOR DEVICE MANUFACTURING APPARATUS

(71) Applicant: SAMSUNG ELECTRONICS CO., LTD., Suwon-si (KR)

(72) Inventors: Dong-wan KIM, Seongnam-si (KR); Seong-sue KIM, Seoul (KR); Chang-young JEONG, Yongin-si (KR); Dong-gun LEE, Hwaseong-si (KR)

(21) Appl. No.: 14/534,340

(22) Filed: Nov. 6, 2014

(30) Foreign Application Priority Data
Nov. 8, 2013 (KR) 10-2013-0135852
Mar. 26, 2014 (KR) 10-2014-0035375

(51) Int. Cl. H01L 21/68; H01L 21/687; H01L 21/673; H01L 21/683

(52) U.S. Cl. CPC H01L 21/682; H01L 21/6831; H01L 21/687; H01L 21/67359
USPC 355/72

(57) ABSTRACT

A semiconductor device manufacturing apparatus includes a mask stage including a mask holder system that fixes a photomask, the mask holder system having a first fixing portion mounted at a first position of the mask holder system to fix the photomask, and a second fixing portion at a second position of the mask holder system and spaced apart from the first position, the second fixing portion fixing a pellicle assembly to be spaced apart from the photomask on the first fixing portion.

### CROSS-REFERENCE TO RELATED APPLICATIONS

Korean Patent Application No. 10-2013-0135852, filed on Nov. 8, 2013, and Korean Patent Application No. 10-2014-0035375, filed on Mar. 26, 2014, in the Korean Intellectual Property Office, and entitled: “Semiconductor Device Manufacturing Apparatus,” are incorporated by reference herein in its entirety.

### BACKGROUND

1. Field

Embodiments relate to a semiconductor device manufacturing apparatus, and more particularly, to a semiconductor device manufacturing apparatus using a photomask.

2. Description of the Related Art

In a semiconductor device manufacturing process, lithography may be used to form circuit patterns on a wafer. In lithography, a photomask is used to transcribe predetermined patterns onto a substrate.

### SUMMARY

According to an aspect of embodiments, there is provided a semiconductor device manufacturing apparatus including a mask stage including a mask holder system that fixes a photomask, wherein the mask holder system includes a first fixing portion mounted at a first position of the mask holder system to fix the photomask; and a second fixing portion mounted at a second position of the mask holder system spaced apart from the first position to fix a pellicle assembly that protects the photomask at a position spaced apart from the photomask.

Each of the first and second fixing portions may be implemented using an electrostatic chuck.

The second fixing portion may include a connection member that fixes the pellicle assembly in a mechanical coupling manner.

The pellicle assembly may include a pellicle frame and a pellicle membrane fixed to the pellicle frame to define a pellicle space in conjunction with the pellicle frame, and the pellicle frame may include a pellicle connection portion that is directly connectable to the second fixing portion of the mask holder system.

The pellicle connection portion may be fixed to the second fixing portion of the mask holder system in a in a chucking manner, mechanical coupling manner, or in an adhesive manner.

The semiconductor device manufacturing apparatus may further include a photomask carrier that protects the photomask in a path along which the photomask is supplied to the mask stage. The photomask carrier may include an inner pod including a base plate that faces a first surface in which a pattern region of the photomask is formed, and a cover that faces a second surface of the photomask opposite to the first surface and defines a space in which the photomask is received in conjunction with the base plate.

The base plate may include a recessed mounting surface formed thereon to receive the pellicle assembly.

The base plate may include a recessed mounting surface formed thereon to receive the pellicle assembly and a base hole formed therein, the base hole being surrounded by the recessed mounting surface and disposed corresponding to the pattern region of the photo mask and a peripheral region of the pattern region.

The pellicle assembly may include a pellicle frame receivable in the recessed mounting surface of the base plate and a pellicle membrane fixed to the pellicle frame and defines a pellicle space in conjunction with the pellicle frame.

The base plate may include a base connection portion that is directly connectable to the second fixing portion of the mask holder system in a state where the pellicle assembly is received in the recessed mounting surface.

The pellicle connection portion may be fixed to the second fixing portion in a chucking manner, in a mechanical coupling manner, or in an adhesive manner.

The base plate may include a recessed mounting surface formed thereon in which the pellicle assembly is mounted, and the pellicle assembly may be fixed onto the recessed mounting surface.

The photomask carrier may further include an outer pod including a shell that provides a space in which the inner pod is received and a door that seals the inner pod in conjunction with the shell.

According to another aspect of embodiments, there is provided a semiconductor device manufacturing apparatus including a mask stage including a mask holder system including a first fixing portion that fixes a photomask, and a second fixing portion mounted at a position spaced apart from the first fixing portion to fix a pellicle assembly that protects the photomask at a position spaced apart from the photomask; and a photomask carrier that protects the photomask in a path along which the photomask is supplied to the mask stage, wherein the photomask carrier includes: a base plate including a recessed mounting surface formed thereon to receive the pellicle assembly and a base hole formed therein, the base hole being surrounded by the recessed mounting surface and disposed corresponding to a pattern region of the photo mask and a peripheral region of the pattern region; and a cover that defines a space in which the photomask is received in conjunction with the base plate.

The second fixing portion of the mask holder system may include a base fixing region that is connectable to an end of the base plate.

According to yet another aspect of embodiments, there is provided a semiconductor device manufacturing apparatus including a mask holder system on a stage, the mask holder system including a first fixing portion at a first position of the stage, and a second fixing portion at a second position of the stage, the second fixing portion being completely separated and spaced apart from the first position, photomask on the first fixing portion of the mask holder system, and a pellicle assembly on the second fixing portion of the mask holder system, the pellicle assembly being spaced apart from the photomask.

The photomask may contacts only the first fixing portion among the first and second fixing portions, and the pellicle assembly may contact only the second fixing portion among the first and second fixing portions.

The semiconductor device manufacturing apparatus may further include a photomask carrier surrounding the photomask and pellicle assembly, the photomask carrier including a base plate including a recessed mounting surface, the pellicle assembly being positioned in the recessed mounting surface, and a cover defining a space for the photomask and the pellicle assembly between the cover and the recessed mounting surface of the base plate.

The photomask carrier may be separable from the stage, the pellicle assembly being an outermost element on the stage.

The cover may overlap the pellicle frame and may be directly attached to the second fixing portion of the mask holder system, the cover being an outermost element on the stage.

### BRIEF DESCRIPTION OF THE DRAWINGS

Features will become apparent to those of ordinary skill in the art by describing in detail exemplary embodiments with reference to the attached drawings, in which:

FIG. 1 illustrates a schematic cross-sectional view of a configuration of a semiconductor device manufacturing apparatus according to embodiments;

FIG. 2A illustrates a schematic plan view of a configuration of a mask stage in the semiconductor device manufacturing apparatus of FIG. 1 according to embodiments;

FIG. 2B illustrates a plan view of a state in which a photomask is fixed to a first fixing portion of the mask stage of FIG. 2A;

FIG. 3A illustrates a cross-sectional view along line III-III′ of FIG. 2B according to embodiments, which illustrates a pellicle frame of FIG. 2B fixed to a second fixing part in a chucking manner using electrostatic force;

FIG. 3B illustrates a cross-sectional view along line III-III′ of FIG. 2B according to other embodiments, which illustrates the pellicle frame of FIG. 2B fixed to the second fixing part using a mechanical fixing tool mounted in the second fixing part;

FIG. 3C illustrates a cross-sectional view along line III-III′ of FIG. 2B according to other embodiments, which illustrates the pellicle frame of FIG. 2B fixed to the second fixing part in an adhesive manner using an adhesive medium;

FIG. 4A illustrates a schematic plan view of a configuration of a mask stage in the semiconductor device manufacturing apparatus of FIG. 1 according to other embodiments;

FIG. 4B illustrates a plan view of a state in which a photomask is fixed to a first fixing portion of the mask stage of FIG. 4A;

FIG. 5 illustrates a schematic cross-sectional view of an exemplary configuration of a photomask carrier that is usable in a semiconductor device manufacturing apparatus according to embodiments;

FIG. 6 illustrates a bottom view of a base plate included in an inner pod of the photomask carrier of FIG. 5;

FIGS. 7A to 7C illustrate schematic cross-sectional views of stages in a process of fixing the photomask to the mask stage in a case of storing and transferring the photomask by using the photomask carrier of FIG. 5;

FIG. 8 illustrates a schematic cross-sectional view of an exemplary configuration of a photomask carrier that is usable in a semiconductor device manufacturing apparatus according to embodiments;

FIG. 9 illustrates a bottom view of a base plate included in the inner pod of the photomask carrier of FIG. 8;

FIGS. 10A to 10C illustrate schematic cross-sectional views of stages in a process of fixing the photomask to the mask stage in a case of storing and transferring the photomask by using the photomask carrier of FIG. 8;

FIG. 11 illustrates a schematic cross-sectional view of an exemplary configuration of a photomask carrier that is usable in a semiconductor device manufacturing apparatus according to embodiments;

FIG. 12 illustrates a diagram of a state in which a photomask, a pellicle assembly, and a base plate are fixed to a mask holder system in the mask stage of the semiconductor device manufacturing apparatus according to embodiments;

FIG. 13 illustrates a schematic cross-sectional view of an exemplary configuration of a photomask carrier that is usable in a semiconductor device manufacturing apparatus according to embodiments;

FIG. 14 illustrates a diagram of a state in which a photomask, a pellicle assembly, and a base plate are fixed to a mask holder system in the mask stage;

FIG. 15 illustrates a flowchart of a method of manufacturing a semiconductor device according to some embodiments;

FIG. 16 illustrates a flowchart of a method of manufacturing a semiconductor device according to other embodiments;

FIG. 17 illustrates a block diagram of a memory card including a semiconductor device manufactured using the semiconductor device manufacturing apparatus according to embodiments; and

FIG. 18 illustrates a block diagram of a memory card including a semiconductor device manufactured using the semiconductor device manufacturing apparatus according to other embodiments.

### DETAILED DESCRIPTION

Hereinafter, embodiments will be described with reference to the accompanying drawings. The embodiments may, however, be embodied in many different forms and should not be construed as being limited to those set forth herein; rather, these embodiments are provided so that this disclosure will be thorough and complete, and will fully convey exemplary implementations to those of skill in the art.

Like reference numerals denote like elements throughout the specification and drawings, and redundant descriptions thereof will be omitted. In addition, though terms like “first” and “second” are used to describe various members, components, regions, layers, and/or portions in various embodiments, the members, components, regions, layers, and/or portions are not limited to these terms. These terms are used only to differentiate one member, component, region, layer, or portion from another one. Therefore, a member, a component, a region, a layer, or a portion referred to as a first member, a first component, a first region, a first layer, or a first portion in an embodiment can be referred to as a second member, a second component, a second region, a second layer, or a second portion in another embodiment.

As used herein, the term “and/or” includes any and all combinations of one or more of the associated listed items. Expressions such as “at least one of,” when preceding a list of elements, modify the entire list of elements rather than the individual elements of the list.

Unless otherwise defined, all terms (including technical and scientific terms) used herein have the same meaning as commonly understood by one of skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

When a certain embodiment may be implemented differently, a specific process order may be performed differently from the described order. For example, two consecutively described processes may be performed substantially at the same time or performed in an order opposite to the described order.

In the accompanying drawings, the dimensions of layers and regions may be exaggerated for clarity of illustration. It will also be understood that when a layer or element is referred to as being “on” another layer or substrate, it can be directly on the other layer or substrate, or intervening layers may also be present. Further, variations from the shapes of the illustrations as a result, for example, of manufacturing techniques and/or tolerances, are to be expected. Thus, embodiments should not be construed as limited to the particular shapes of regions illustrated herein but may be construed to include deviations in shapes that result, for example, from manufacturing.

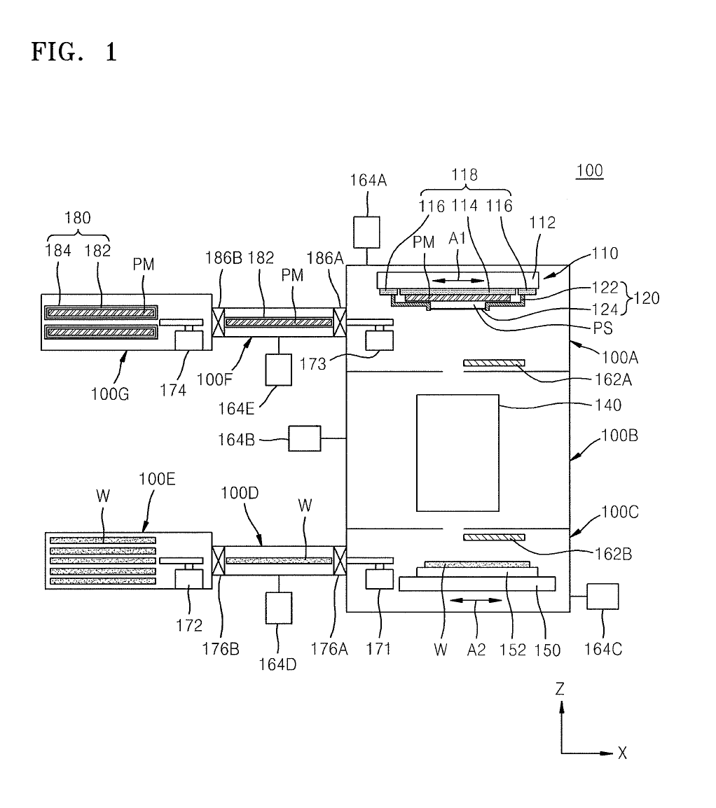

FIG. 1 is a cross-sectional view schematically illustrating a configuration of a semiconductor device manufacturing apparatus 100 according to embodiments. In FIG. 1, the semiconductor device manufacturing apparatus 100 includes an exposure apparatus that reduces and transcribes an image of patterns formed on a photomask (also referred to as a “reticle”) onto a wafer using extreme ultra violet (EUV) light in vacuum in a projection optical system.

Referring to FIG. 1, the semiconductor device manufacturing apparatus 100 includes a mask stage region 100A, a projection optical region 100B, and a wafer stage region 100C.

A mask stage 110 placed in the mask stage region 100A includes a mask stage supporter 112 and a mask holder system 118 including a first fixing portion 114 and a second fixing portion 116 respectively fixed to the mask stage supporter 112. The first fixing portion 114 of the mask holder system 118 is mounted at a predetermined position to fix a photomask PM, e.g., the first fixing portion 114 may be attached to a center of the mask stage supporter 112. The function of the second fixing portion 116 is to fix a pellicle assembly 120, which protects the photomask PM, at a position spaced apart from the photomask PM. The second fixing portion 116 is mounted on the mask stage supporter 112 at a position spaced apart from the first fixing portion 114, e.g., the second fixing portion 116 may be attached to a periphery of the mask stage supporter 112.

In some embodiments, the first fixing portion 114 may include an electrostatic chuck. In this case, the first fixing portion 114 may retain, e.g., hold, the photomask PM by absorbing the photomask PM by an electrostatic force.

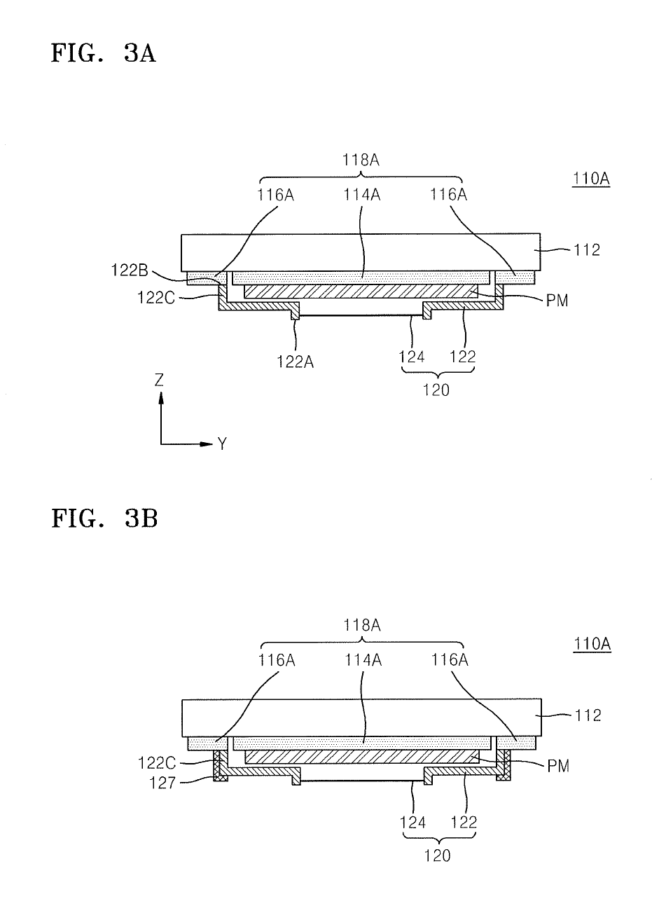

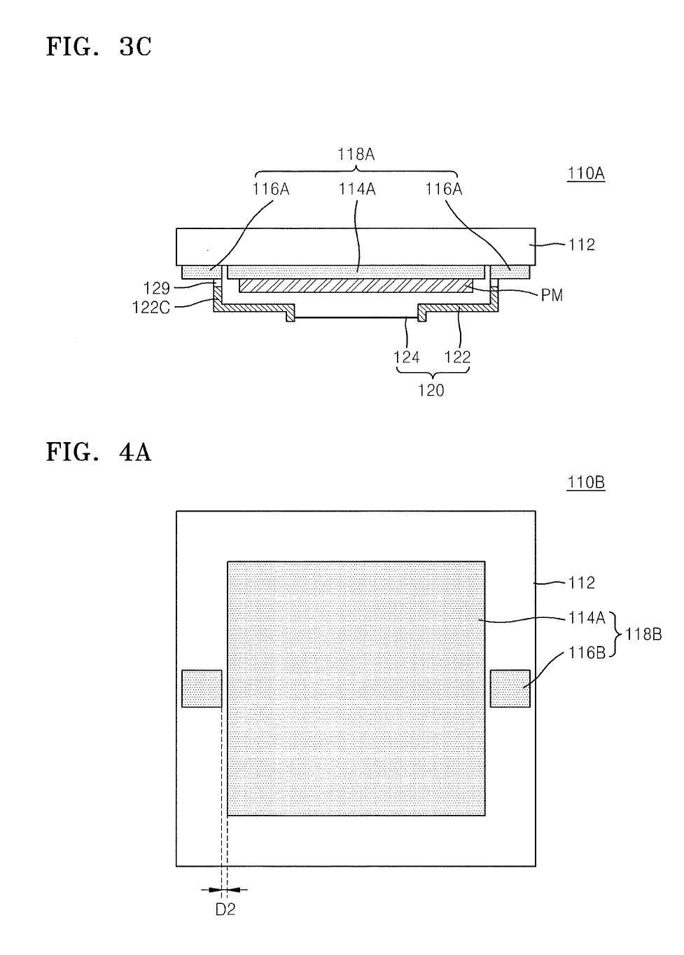

The pellicle assembly 120 includes a pellicle frame 122 and a pellicle membrane 124 that is fixed to the pellicle frame 122 and defines a pellicle space PS. For example, as illustrated in FIG. 1, the pellicle membrane 124 may be aligned with and overlap the photomask PM, such that the pellicle space PS may be defined between the pellicle membrane 124 and a surface of the photomask PM facing the pellicle membrane 124. The pellicle space PS receives the photomask PM in conjunction with the pellicle frame 122. A pellicle connection portion that is directly connectable to the second fixing portion 116 of the mask holder system 118 may be provided at an end of the pellicle frame 122. A detailed description for the pellicle connection portion will be given with reference to FIGS. 3A to 3C.

In some embodiments, the second fixing portion 116 may be implemented using an electrostatic chuck. In this case, the pellicle frame 122 is retained to be absorbed by the second fixing portion 116 by electrostatic force.

In some embodiments, at least one of the second fixing portion 116 and the pellicle frame 122 may include a coupling member that fixes the second fixing portion 116 and the pellicle frame 122 to each other in a mechanical coupling manner. The coupling member may include, e.g., a clamp or a screw, but embodiments are not limited thereto.

In some embodiments, an end of the pellicle frame 122 may be fixed to the second fixing portion 116 in an adhesive manner. To this end, adhesive may be used to fix the end of the pellicle frame 122 to the second fixing portion 116.

Although the end of the pellicle frame 122 is illustrated as being directly fixed to the second fixing portion 116 of the mask holder system 118 in FIG. 1, embodiments are not limited thereto. For example, the pellicle frame 122 may be fixed by another medium, e.g., a portion of a photomask carrier used to protect the pellicle frame 122 during transfer of the pellicle frame 122, which will be described in detail below with reference to FIGS. 8 to 14.

The mask stage 110 that is supported by the mask stage supporter 112 may transfer the photomask PM fixed to the first fixing portion 114 in a scan direction as indicated by an arrow A1.

In the projection optical region 100B, there is disposed a projection optical system 140 that transcribes patterns formed on the photomask PM onto a wafer W placed in the wafer stage region 100C. The wafer W may be fixed to and retained on a wafer chuck 152. The wafer chuck may be on a wafer stage 150. The wafer chuck 152 may transfer the wafer W in a scan direction as indicated by an arrow A2.

The mask stage region 100A, in which the mask stage 110 is placed, the projection optical region 100B, in which the projection optical system 140 is placed, and the wafer stage region 100C, in which the wafer stage 150 is placed, may be separated from each other by first and second gate valves 162A and 162B. Vacuum exhaust apparatuses 164A, 164B, and 164C may be connected respectively to the mask stage region 100A, the projection optical region 100B, and the wafer stage region 100C, allowing independent pressure control within each of the regions.

A carrying hand 171, i.e., a carrier unit 171, that loads and unloads the wafer W on the wafer chuck 152 may be mounted between the wafer stage region 100C and a load lock chamber 100D. A vacuum exhaust apparatus 164D may be connected to the load lock chamber 100D. The wafer W may be temporarily stored in a wafer load port 100E under atmospheric pressure. A carrying hand 172 that loads and unloads the wafer W may be mounted between the load lock chamber 100D and the wafer load port 100E. A gate valve 176A may be disposed between the wafer stage region 100C and the load lock chamber 100D. A gate valve 176B may be disposed between the load lock chamber 100D and the wafer load port 100E.

A carrying hand 173 that loads and unloads the photomask PM may be mounted between the mask stage 110 in the mask stage region 100A and a mask load lock chamber 100F. A vacuum exhaust apparatus 164E may be connected to the mask load lock chamber 100F. The photomask PM may be temporarily stored in a mask load port 100G under atmospheric pressure. A carrying hand 174 that loads and unloads the photomask PM may be mounted between the mask load lock chamber 100F and the mask load port 100G. A gate valve 186A may be disposed between the mask stage region 100A and the mask load lock chamber 100F. A gate valve 186B may be disposed between the mask load lock chamber 100F and the mask load port 100G.

The photomask PM may be stored and transferred in a photomask carrier 180 when being transferred from the outside to the semiconductor device manufacturing apparatus 100. The photomask PM may be transferred to the mask load port 100G in the state of being received in the photomask carrier 180. That is, the photomask PM may be transferred while being inside the photomask carrier 180, and may be stored in the mask load port 100G while being inside the photomask carrier 180, i.e., the photomask carrier 180 with the photomask PM therein may be positioned inside the mask load port 100G. Therefore, the photomask PM may be protected efficiently from unnecessary contact with an external environment and pollution by external particles.

The photomask carrier 180 may include an inner pod 182 and an outer pod 184 that provides a space in which the inner pod 182 is received. The inner pod 182 and the outer pod 184 may be implemented using a standard mechanical interface (SMIF) pod complying with the Semiconductor Equipment and Materials International (SEMI) standard E 152-0709. The outer pod 184 may be called a “reticle SMIF pod”. The outer pod 184 may protect the photomask PM when the photomask PM is transferred between different manufacturing stations or between different positions. The inner pod 182 may protect the photomask PM while the photomask PM is transferred to a vacuum atmosphere or to the mask stage 110 or a position around the mask stage 110. When an air pressure in a surrounding environment is changed from atmospheric pressure to vacuum pressure or vice versa, an eddy of pollutant particles may be caused. As a result, the pollutant particles surrounding the photomask PM may cause pollution of the photomask PM. The inner pod 182 may protect the photomask PM from such an environment until the photomask PM is transferred to a vacuum atmosphere or to the mask stage 110 or a position near the mask stage 110.

In the semiconductor device manufacturing apparatus 100 illustrated in FIG. 1, the photomask PM may be retained in a state of being protected by the inner pod 182 and the outer pod 184 until the photomask PM is transferred from the outside to the mask load port 100G. Before the photomask PM is transferred from the mask load port 100G to the mask load lock chamber 100F, the outer pod 184 may be separated from the inner pod 182 within the mask load port 100G, and the photomask PM may be transferred to the mask load lock chamber 100F in a state of being protected by the inner pod 182 alone.

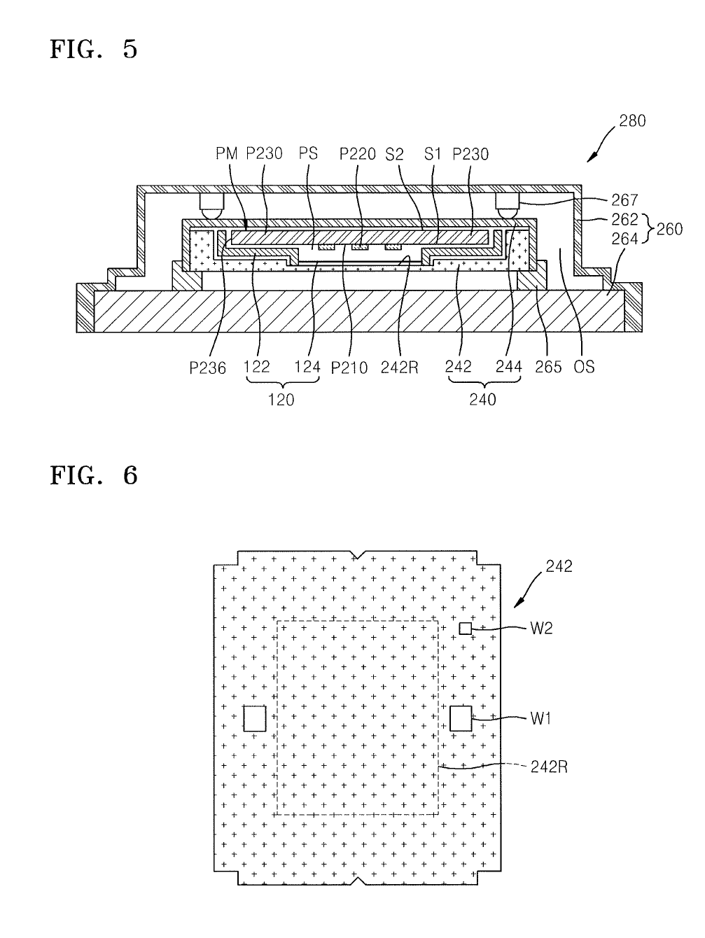

In the mask load lock chamber 100F, a cover and a base plate of the inner pod 182 may be separated from each other to expose the photomask PM. That is, the cover of the inner pod 182 that covers a back side of the photomask PM may be separated from the base plate of the inner pod 182 that covers a front side of the photomask PM, in which a pattern region of the photomask PM is formed, resulting in exposure of the back side of the photomask PM. For example, as illustrated in FIG. 5, a cover 244 on a back side of the photomask PM may be separated from a base plate 242 that covers a front side of the photomask PM, resulting in exposure of the back side of the photomask PM. Thereafter, the photomask PM may be transferred from the mask load lock chamber 100F to the mask stage region 100A with the back side exposed. The exposed back side of the photomask PM may be fixed to the first fixing portion 114 of the mask holder system 118, while the front side of the photomask PM remains covered by the base plate of the inner pod 182, e.g., by the base plate 242 in FIG. 5.

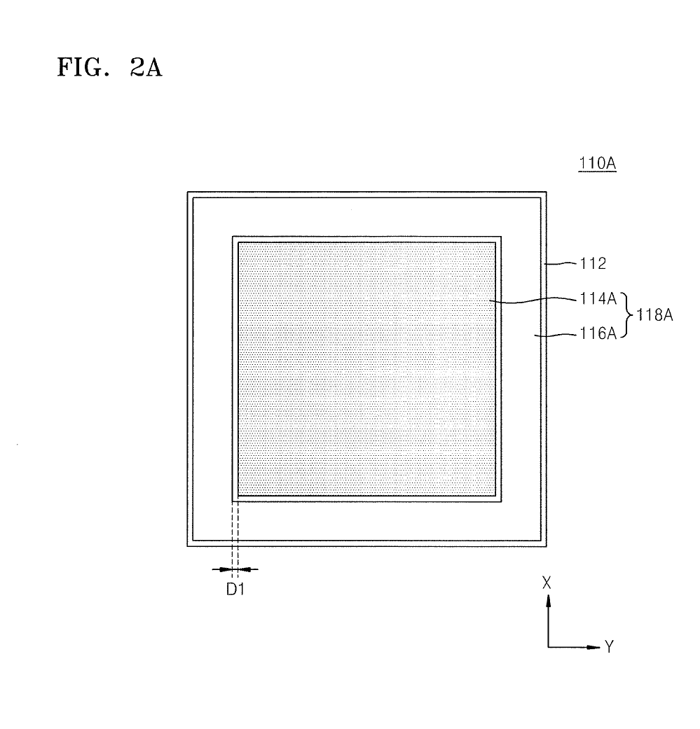

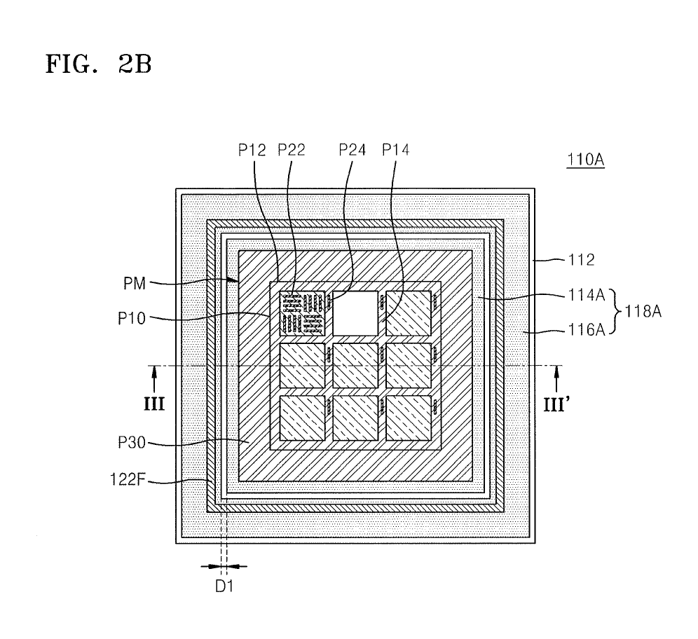

FIG. 2A is a plan view schematically illustrating a configuration of a mask stage 110A that is applicable as the mask stage 110 included in the mask stage region 100A of the semiconductor device manufacturing apparatus 100 of FIG. 1, according to an embodiment.

Referring to FIG. 2A, a mask holder system 118A of the mask stage 110A includes a first fixing portion 114A and a second fixing portion 116A that are fixed to the mask stage supporter 112. The second fixing portion 116A has a shape entirely, e.g., continuously, surrounding the, e.g., entire, first fixing portion 114A on the mask stage supporter 112. The first fixing portion 114A and the second fixing portion 116A are spaced apart from each other at a first distance D1, e.g., the first and second fixing portions 114A and 116A may be concentric. In some embodiments, the first distance D1 may be in a range of several micrometers to several tens of micrometers.

FIG. 2B is a plan view illustrating a state where the photomask PM is fixed to the first fixing portion 114A of the mask stage 110A of FIG. 2A. FIG. 2B illustrates a position 122F, i.e., a position at which the pellicle frame 122 is fixed to the second fixing portion 116A.

In FIG. 2B, the photomask PM with a reflective photomask structure is exemplarily illustrated. The photomask PM may be a reflective photomask which may be used in lithography using a EUV wavelength, e.g., a 13.5 nm wavelength, for exposure. The photomask PM may include a pattern region P10 for transcription of patterns onto the wafer W (FIG. 1) and a black border region P30 surrounding the pattern region P10. The pattern region P10 may include a main pattern region P12, in which main pattern elements P22 for transcription of patterns onto a chip region on the wafer W are formed, and an auxiliary pattern region P14, in which auxiliary pattern elements P24 for transcription of patterns onto a scribe lane region of the wafer W are formed. The black border region P30 may be formed on a non-pattern region having no pattern element for transcription of patterns onto the wafer. Although one main pattern region P12 selected from a plurality of main pattern regions P12 included in the photomask PM is illustrated as including the main pattern elements in FIG. 2B, this is for convenience of description and illustration, and embodiments are not limited thereto.

In the mask holder system 118A, the photomask PM may be fixed to the first fixing portion 114A, and the pellicle frame 122 may be fixed to the second fixing portion 116A.

In some embodiments, the first fixing portion 114A may be implemented using an electrostatic chuck. The photomask PM may be fixed to the first fixing portion 114A using Coulomb force or Johnson-Rahbeck force (hereinafter, referred to as “electrostatic force”) in a chucking manner. To this end, a conductive film may be formed on the back side of the photomask PM facing the first fixing portion 114A.

In some embodiments, the second fixing portion 116A may be implemented using an electrostatic chuck similarly to the first fixing portion 114A. The pellicle frame 122 may be fixed to the second fixing portion 116A by an electrostatic force in a chucking manner similarly to the manner of fixing the photomask PM as described above. To this end, the pellicle frame 122 may be formed by a conductor, e.g., the pellicle frame 122 may be formed of a conductive material.

In some embodiments, the pellicle frame 122 may be fixed to the second fixing portion 116A in a mechanical coupling manner. For example, the pellicle frame 122 may be fixed to the second fixing portion 116A using a mechanical coupling member, e.g. a clamp or a screw. In some embodiments, the pellicle frame 122 may be fixed to the second fixing portion 116A in an adhesive manner.

FIG. 3A is a cross-sectional view taken along line III-III′ of FIG. 2B according to an embodiment. FIG. 3A illustrates the pellicle frame 122 of FIG. 2B fixed to the second fixing portion 116A in a chucking manner using an electrostatic force.

Referring to FIG. 3A, the pellicle membrane 124 may be fixed to a first end 122A of the pellicle frame 122. A second end of the pellicle frame 122 may include a pellicle connection portion 122C that may be directly connected to the second fixing portion 116A via an electrostatic force. For example, as illustrated in FIG. 3A, an entire terminal end 122B of the pellicle connection portion 122C, i.e., an entire surface of the pellicle connection portion 122C facing the second fixing portion 116A, may contact the second fixing portion 116A, such that a surface of the second fixing portion 116A facing the first fixing portion 114A is aligned, e.g., coplanar, with a surface of the pellicle connection portion 122C facing the photomask PM. As such, the entire pellicle frame 122 is spaced apart, e.g., completely separated, from the first fixing portion 114A with the photomask PM.

FIG. 3B is a cross-sectional view taken along line III-III′ of FIG. 2B according to another embodiment. FIG. 3B illustrates the pellicle frame 122 of FIG. 2B fixed to the second fixing portion 116A by using a mechanical fixing tool 127 mounted in the second fixing portion 116A.

Referring to FIG. 3B, in some embodiments, the mechanical fixing tool 127 may include a clamp. In some embodiments, the mechanical fixing tool 127 may have a structure including a screw.

The pellicle membrane 124 may be fixed to the first end 122A of the pellicle frame 122. The second end of the pellicle frame 122 may include the pellicle connection portion 122C that may be directly connected to the second fixing portion 116A by using the mechanical fixing tool 127.

FIG. 3C is a cross-sectional view taken along line III-III′ of FIG. 2B according to still another embodiment. FIG. 3C illustrates the pellicle frame 122 of FIG. 2B fixed to the second fixing portion 116A in an adhesive manner using an adhesive medium 129.

Referring to FIG. 3C, in some embodiments, the adhesive medium 129 may be formed of, e.g., a silicon resin adhesive, a fluorine resin adhesive, or an acryl adhesive, but embodiments are not limited to the composition described above. The pellicle connection portion 122C of the pellicle frame 122 may be fixed to the second fixing portion 116A using the adhesive medium 129.

The pellicle membrane 124 may be fixed to the first end 122A of the pellicle frame 122. The second end of the pellicle frame 122 may include the pellicle connection portion 122C which may be connected directly to the second fixing portion 116A via the adhesive medium 129.

In the mask stage 110A described with reference to FIGS. 2A to 3C, the first fixing portion 114A and the second fixing portion 116A are spaced apart from each other, e.g., completely separated from each other, by the first distance D1. For example, as illustrated in FIG. 2A, the first and second fixing portions 114A and 116A are concentric, such that the second fixing portion 116A is spaced apart from the first fixing portion 114A by the first distance D1 along the entire perimeter of the first fixing portion 114A. Therefore, the pellicle frame 122, which is fixed to the second fixing portion 116A, is fixed at a position spaced apart from the photomask PM, which is fixed to the first fixing portion 114A, at least by the first distance D1. Accordingly, a path, i.e., along which heat absorbed by the pellicle frame 122 during an exposure process may be delivered to the photomask PM, may be blocked.

In other words, as the second fixing portion 116A with the pellicle frame 122 are separated, e.g., completely separated, from the first fixing portion 114A with the photomask PM, heat absorbed by the pellicle frame 122 during a wafer exposure process may not be transferred to the first fixing portion 114A with the photomask PM. Similarly, deformation of the pellicle frame 122 due to heat adsorption, heat, or stress may be prevented from being delivered to or affecting the photomask PM. Therefore, an error, e.g., a registration error or a flatness error, in the photomask PM, e.g., when the pattern region of the photomask PM is deformed or deteriorated, e.g., due to heat absorbed in the pellicle frame 122, may be prevented from occurring in the photomask PM. In addition, other problems, e.g., defocusing of an exposure apparatus and a wafer overlay error, may be prevented or substantially minimized.

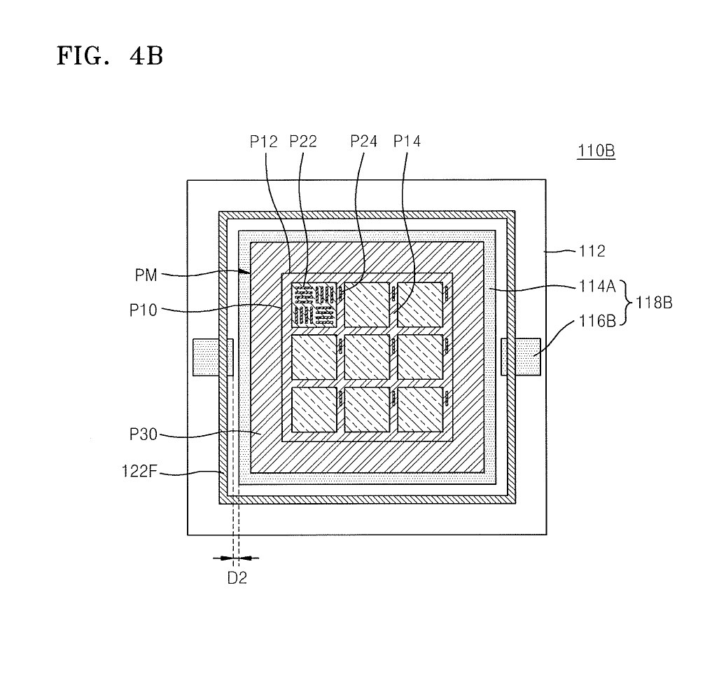

FIG. 4A is a schematic plan view illustrating a configuration of a mask stage 110B according to another embodiment. The mask stage 110B in FIG. 4A is usable as the mask stage 110 included in the mask stage region 100A of the semiconductor device manufacturing apparatus 100 of FIG. 1.

Referring to FIG. 4A, a mask holder system 118B of the mask stage 110B includes the first fixing portion 114A and a plurality of second fixing portions 116B which are fixed to the mask stage supporter 112. On the mask stage supporter 112, the plurality of second fixing portions 116B may be disposed at a plurality of positions around the first fixing portion 114A selected from positions spaced apart from the first fixing portion 114A by a second distance D2. For example, as illustrated in FIG. 4A, the plurality of second fixing portions 116B may include two discrete portions at opposite sides of the mask holder system 118B, with each of the discrete portions being spaced apart by the second distance D2 from the first fixing portion 114A. In some embodiments, the second distance D2 may be in a range of several micrometers to several tens of micrometers.

FIG. 4B is a plan view illustrating a state where a photomask PM is fixed to the first fixing portion 114A of the mask stage 110B of FIG. 4A. FIG. 4B illustrates the position 122F of the pellicle frame 122 which is fixed at a position spaced apart from the photomask PM on the mask stage supporter 112.

The pellicle frame 122 may be fixed to the second fixing portion 116B using any one of the fixing methods described with reference to FIGS. 3A to 3C. Although two second fixing portions 116B are illustrated as being respectively disposed at both sides of the first fixing portion 114A in FIGS. 4A and 4B, embodiments are not limited thereto. For example, the plurality of second fixing portions 116B may be disposed at positions spaced apart from the first fixing portion 114A by a predetermined distance at equal intervals or different intervals around the first fixing portion 114A on the mask stage supporter 112, and the number and positions thereof may be selected according to necessity.

In an exposure process of semiconductor device manufacturing processes, latent image patterns are formed on a resist film by projecting and exposing patterns formed in the photomask (reticle) onto the wafer on which the resist film is formed, and resist patterns are formed on the wafer through a developing process. However, when foreign material, e.g., a particle, exists on the photomask, the foreign material is transcribed onto the wafer along with the patterns, thereby causing pattern defect.

In detail, in a conventional semiconductor device manufacturing process, a pellicle may be attached, e.g., directly, to the photomask using adhesive to protect the pattern region of the photomask to prevent such a problem. The photomask is released and is then used in a wafer exposure process for a predetermined period of time. Thereafter, the photomask is cleaned, inspected, and repaired for rework of the photomask. To this end, the pellicle is demounted from the surface of the photomask, and the photomask rework process is performed. Thereafter, the pellicle is again mounted on the reworked photomask. Therefore, in a conventional semiconductor device manufacturing process, the photomask is not used for the exposure process during the photomask rework process, thereby causing reduction in productivity.

Further, when a conventional pellicle is mounted on the photomask, foreign material, e.g., a particle, may fall onto a front side of the photomask, in which the pattern region is positioned, or the front side may be polluted. Therefore, in an inspection process performed after mounting the conventional pellicle, a defect which has not been detected before the rework process may be detected. In this case, the conventional pellicle is again demounted from the photomask and an additional process, e.g., a cleaning process, may be performed. Thereafter, the conventional pellicle is again mounted on the photomask, thereby causing inconvenience. Further, a turn around time (TAT) for rework of the photomask is increased, thereby causing reduction in productivity.

Furthermore, when an adhesive is used to attach the conventional pellicle, e.g., directly, to the front side of the photomask, it may be difficult to separate the pellicle from the photomask for rework of the photomask, or the adhesive used for attaching the conventional pellicle may not be sufficiently removed. In this case, when a cleaning process is strengthened for removal of the adhesive, the photomask may be damaged, thereby shortening the lifecycle of the photomask.

In addition, in the case where the conventional pellicle is attached, e.g., directly, to the surface of the photomask with adhesive, sufficient inspection sensitivity may be secured when the pellicle is transparent with respect to light used in a photomask inspection apparatus for inspection of the patterns on the photomask. However, the material selection for the transparent pellicle membrane or selection of an inspection apparatus may be limited.

Also, when an exposure process is performed while the conventional pellicle is attached, e.g., directly, to the surface of the photomask, the patterns of the photomask may be deformed and deteriorated due to heat absorbed by the pellicle, thereby causing an error, e.g., a registration error or a flatness error, in the photomask. As a result, defocusing may occur in the exposure apparatus and there is a possibility of an adverse effect on wafer overlay characteristics.

In contrast, according to embodiments, the second fixing portion 116A illustrated FIGS. 2A and 2B or the plurality of second fixing portions 116B illustrated in FIGS. 4A and 4B are spaced apart, e.g., completely separated, from the first fixing portion 114A by a predetermined distance. Therefore, the pellicle frame 122 may be fixed to a position spaced apart from the photomask PM. Accordingly, loss in productivity may be minimized, which is caused upon mounting/demounting of the pellicle assembly 120 on/from the mask stage 110, and damage and deterioration of the photomask PM may be prevented. In addition, a path, i.e., along which heat absorbed by the pellicle frame 122 during the exposure process could be delivered to the photomask PM via the second fixing portion 116A, may be blocked, thereby preventing heat or stress from being delivered to the photomask PM even when the heat is absorbed by the pellicle frame 122 or the pellicle frame 122 is deformed due to the heat absorption. Therefore, an error, e.g., a registration error or a flatness error, may be prevented from occurring in the photomask PM, e.g., deformation or deterioration of the pattern region of the photomask PM due to heat or stress may be prevented or substantially minimized. In addition, problems may be prevented from arising due to defocusing of an exposure apparatus or due to a wafer overlay error.

In a semiconductor device manufacturing process using ultra-fine patterns, e.g., large-scale integration (LSI) or very-large-scale integration (VLSI), a projection stepper may be used, which reduces and projects patterns formed on a photomask onto a resist film formed on a wafer to form latent image patterns on the resist film. With an increase in mounting density of semiconductor devices, circuit patterns become finer. Therefore, an exposure line width is to be finer in an exposure apparatus. Accordingly, a method for shortening wavelength of exposure light has been developed to improve definition performance of the exposure apparatus, e.g., i-line (365 nm), a krypton fluoride (KrF) excimer laser (248 nm), an argon fluoride (ArF) excimer laser (193 nm), and a fluorine (F₂) excimer laser (157 nm).

For example, an exposure apparatus using EUV having a wavelength of about 10-15 nm in a soft x-ray range or an electron beam has been developed. The wavelength of the exposure light is shortened to that of the EUV light or electron beam, and thus light does not penetrate the air under atmospheric pressure. Therefore, a light path of the exposure light is to be in a high-vacuum environment. Therefore, an optical system, a mask stage, and a wafer state are disposed within a vacuum chamber, and load lock chambers are mounted at outlets at which the wafer and the photomask are unloaded. In a state where vacuum is maintained, the wafer or the photomask may be loaded or unloaded.

In a conventional EUV exposure process, a reflective photomask including multiple reflective films on a front side, in which a pattern region is formed, may be used as a photomask. When the wavelength of exposure light is shortened to within a EUV range, the exposure process is performed without using the pellicle because of limitations in selection of transparent material for EUV exposure. When the exposure process is performed without using the pellicle, the photomask is not protected from particle pollution which may occur during the EUV exposure process.

In contrast, the semiconductor device manufacturing apparatus according to embodiments protects the photomask PM by using the pellicle assembly 120 even in an exposure process using a EUV light source, thereby preventing the photomask PM from being polluted during the exposure process.

FIG. 5 is a schematic cross-sectional view of an exemplary configuration of a photomask carrier 280 which may be used instead of the photomask carrier 180 of FIG. 1 in a semiconductor device manufacturing apparatus according to embodiments.

Referring to FIG. 5, the photomask carrier 280 may be used to protect the photomask PM in a path along which the photomask PM having a plurality of pattern elements P220 formed in a pattern region P210 on the front side of the photomask PM is provided to the mask stage 110 (see FIG. 1).

The photomask carrier 280 includes an inner pod 240 and an outer pod 260. The outer pod 260 may protect the photomask PM when the photomask PM is transferred between different manufacturing stations or between different positions. The inner pod 240 may protect the photomask PM while the photomask PM is transferred to the mask stage 110 (see FIG. 1) or to a position near the mask stage 110.

The inner pod 240 includes the base plate 242 that faces a front side of the photomask PM, i.e., a first surface S1, having the pattern region P210 in which the plurality of pattern elements P220 are formed, and the cover 244 that faces a back side of the photomask PM, i.e., a second surface S2, opposite to the first surface S1. The base plate 242 and the cover 244 define a space receiving the photomask PM therebetween in conjunction with each other.

A recessed mounting surface 242R that receives the pellicle assembly 120 is formed in the base plate 242. In some embodiments, the pellicle assembly 120 may be fixed onto the recessed mounting surface 242R in an adhesive manner. In some embodiments, the pellicle assembly 120 may be supported on the recessed mounting surface 242R without a separate fixing member because the recessed mounting surface 242R functions as a supporting surface.

In some embodiments, the base plate 242 and the cover 244 of the inner pod 240 may be formed of a polymer material, e.g., polyimide, polyetherimide, poly methyl methacrylate, or carbon fiber-filled polycarbonate. In some embodiments, the base plate 242 and the cover 244 of the inner pod 240 may be formed of Pyrex glass. In some embodiments, the base plate 242 and the cover 244 may be formed through an injection molding process or another appropriate manufacturing process using a rigid thermoplastic polymer.

In some embodiments, the base plate 242 and the cover 244 of the inner pod 240 may be formed of a transparent material, such that the photomask PM received therein may be viewed from the outside. However, embodiments are not limited thereto. For example, the base plate 242 and the cover 244 of the inner pod 240 may be formed of a transparent material or a semi-transparent material. The materials for the base plate 242 and the cover 244 of the inner pod 240 are not limited to those described above, and various suitable materials may be used.

The pellicle assembly 120 may include the pellicle frame 122 that may be received in the recessed mounting surface 242R of the base plate 242, and the pellicle membrane 124 that is fixed to the pellicle frame 122 to define the pellicle space PS in conjunction with the pellicle frame 122.

In some embodiments, the pellicle frame 122 may be formed of a metal, alloy, or polymer. For example, the pellicle frame 122 may be formed of aluminum, an aluminum alloy, stainless steel, or polyethylene. In some embodiments, the pellicle frame 122 may be formed in a rectangular plane shape. However, the shape of the pellicle frame 122 is not limited to a rectangle and may be any other shape according to necessity. The pellicle frame 122 may have a structure that is bent so as to surround a black border region P230 on the first surface S1 of the photomask PM and sides P236 of the photomask PM. The black border region P230 is a non-pattern region having no pattern element for transcription of patterns onto a wafer.

In some embodiments, the pellicle membrane 124 may be formed of a material having a high transmittance with respect to an exposure light. For example, the pellicle membrane 124 may be formed of silicon, cellulosic resin, e.g., nitrocellulose or cellulose acetate, or fluorine resin. The pellicle membrane 124 may be fixed to the pellicle frame 122 using an adhesive, e.g., epoxy resin or fluorine resin.

The outer pod 260 may include a shell 262 that provides a space OS, in which the inner pod 260 is received, and a door 264 that seals the inner pod 240 in conjunction with the shell 262. Support pins 265 may protrude from an inner surface of the door 264, and pressing members 267, e.g., a ball bearing, may be mounted on an inside upper wall of the shell 262.

When the inner pod 240 is received in the inner space of the outer pod 260, the base plate 242 of the inner pod 260 is supported by the support pins 265, and the pressing members 267 may press the cover of the inner pod 260. When the inner pod 240 is transferred, while in a state of being sealed within the outer pod 260, the pressure by the pressing members 262 prevents the inner pod 240, which receives the photomask PM, from shaking or vibrating unintentionally within the inner space of the outer pod 260, thereby preventing generation of unnecessary particles within the inner pod 240 or damage to the photomask PM.

Materials of the shell 262 and the door 264 of the outer pod 260 are similar to those of the base plate 242 and the cover 244 of the inner pod 240 as described above, but are not limited thereto.

The photomask carrier 280 provides the space that receives the pellicle assembly 120 within the inner pod 240, allowing the photomask PM to be transferred while in a state of being protected by the pellicle assembly 120 during transfer of the photomask PM. In addition, the photomask PM and the pellicle assembly 120 are doubly protected by the inner pod 240 and the outer pod 260, thereby maintaining sealability of the space in which the photomask PM is received.

The pellicle assembly 120 received within the inner pod 240 may be disposed apart from the photomask PM. In some embodiments, when the photomask PM is received within the inner pod 240, the pellicle assembly 120 and the photomask PM may be retained to be spaced apart from each other by a distance of several micrometers. As described above, the distance between the pellicle assembly 120 and the photomask PM may be retained as it is when the photomask PM and the pellicle assembly 120 are fixed to the mask stage 110 (see FIG. 1). As described above, the pellicle assembly 120 is disposed apart from the photomask PM, thereby facilitating the mounting or demounting of the pellicle assembly 120 relative to the mask stage 110.

FIG. 6 is a bottom view illustrating the base plate 242 included in the inner pod 240 of the photomask carrier 280 of FIG. 5.

Referring to FIG. 6, the recessed mounting surface 242R, in which the pellicle assembly 120 may be mounted, may be disposed in an approximately central portion of the base plate 242. The recessed mounting surface 242R may be of a closed structure having no opening. Alignment windows W1 and a data matrix window W2 may be formed in a portion of the base plate 242, which faces the black border region P30 (see FIG. 4B) of the photomask PM received within the inner pod 240. The positions and numbers of the alignment window W1 and the data matrix window W2 are not limited to those illustrated in FIG. 6.

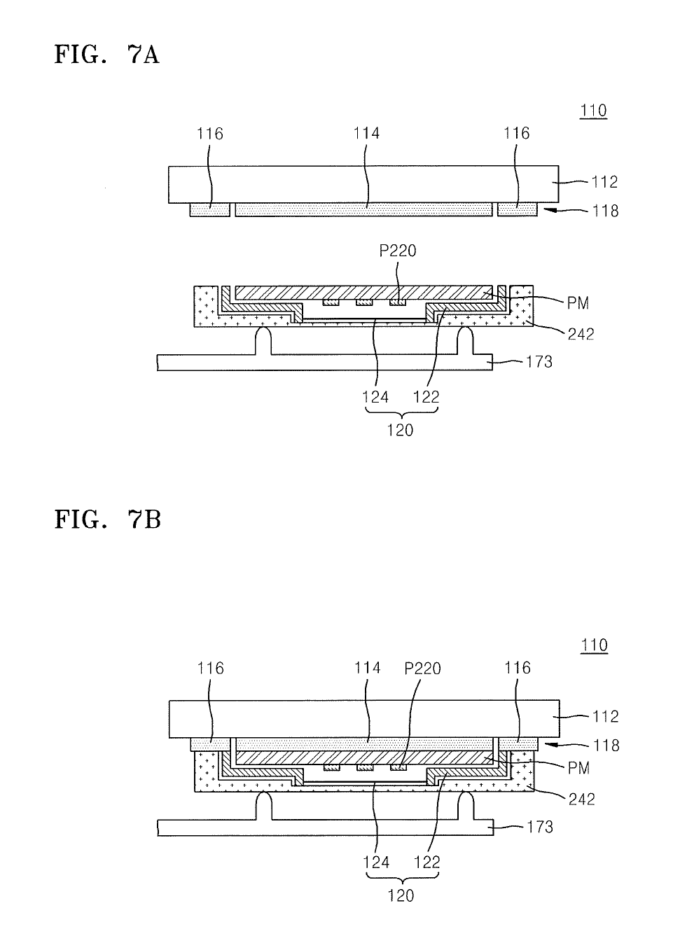

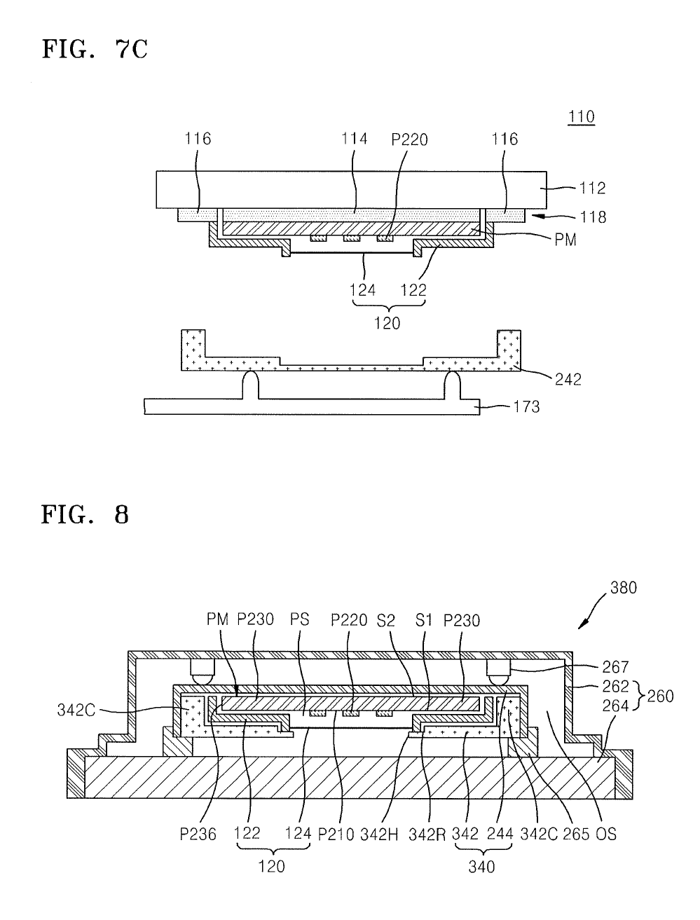

FIGS. 7A to 7C are schematic cross-sectional views illustrating stages in a process of fixing the photomask PM to the mask stage 110 in a case of storing and transferring the photomask PM using the photomask carrier 280 of FIG. 5.

Referring to FIG. 7A, after the photomask PM received within the photomask carrier 280 has been transferred from the outside to the mask load port 100G of the semiconductor device manufacturing apparatus 100 (FIG. 1), the outer pod 260 is separated from the inner pod 240 in the mask load port 100G. The photomask PM is transferred to the mask load lock chamber 100F while being received, e.g., maintained, within the inner pod 240. Thereafter, the cover 244 of the inner pod 240 is separated and removed from the base plate 242 within the mask load lock chamber 100F, and the back side of the photomask PM may be exposed. Thereafter, the photomask PM is transferred to the mask stage region 100A with the back side exposed.

In detail, the base plate 242 with the photomask PM is transferred by the carrying hand 173 within the mask stage 110 from the mask load lock chamber 100F to the mask stage region 100A, while the photomask PM is being maintained within the base plate 242 of the inner pod 240 (see FIG. 5). That is, in the state in which the front side of the photomask PM, in which the plurality of pattern elements P220 are formed, is covered by the pellicle assembly 120 and the base plate 242, the base plate 242 receives the photomask PM and is supported by the carrying hand 173. The movement of the photomask PM is controlled by the carrying hand 173.

Referring to FIG. 7A, the photomask PM is positioned in the mask stage region 100A to be aligned with the first fixing portion 114 and under the first fixing portion 114 of the mask holder system 118. An upper end of the pellicle assembly 120 and an upper end of the base plate 242 are positioned to be aligned with the second fixing portion 116 and under the second fixing portion 116 of the mask holder system 118.

Referring to FIG. 7B, the base plate 242, in which the photomask PM is received, is moved using the carrying hand 173, and the photomask PM is fixed to the first fixing portion 114 of the mask holder system 118. In this case, the upper end of the pellicle assembly 120 may be fixed to the second fixing portion 116 of the mask holder system 118.

Referring to FIG. 7C, while the photomask PM is fixed to the first fixing portion 114 of the mask holder system 118 and the upper end of the pellicle assembly 120 is fixed to the second fixing portion 116 of the mask holder system 118, the base plate 242 is separated and spaced apart from the pellicle assembly 120 and the second fixing portion 116. As a result, the pellicle assembly 120 is exposed. The movement of the base plate 242 may be controlled by the carrying hand 173. Thereafter, while the photomask PM is covered by the pellicle assembly 120, a wafer exposure process is performed using the photomask PM.

As described with reference to FIGS. 7A to 7C, the photomask PM is received within the inner pod 240 and is transferred to the mask stage 110, while the front side of the photomask PM, on which the plurality of pattern elements P220 are formed, is covered by the pellicle assembly 120, thereby preventing the pattern region of the photomask PM from being exposed to the outside. Therefore, a possibility of pollution of the photomask PM may be reduced and reliability of the exposure process may be improved.

When the photomask PM is fixed to the mask holder system 118 of the mask stage 110, foreign material may be inserted between the mask holder system 118 and the photomask PM or foreign material existing in the mask stage 110 may move to a surface of the photomask PM to pollute the photomask PM. When the photomask PM is polluted by the foreign material, the photomask PM may be deformed, or the surface of the pattern region of the photomask PM may be deteriorated, causing an error in the wafer exposure process and a reduction in productivity. Therefore, foreign material having a fine size may be unfavorable in exposure precision of the wafer exposure process, e.g., in a EUV exposure process.

Therefore, in the semiconductor device manufacturing apparatus 100 according to embodiments, the pellicle frame 122 of the pellicle assembly 120 and the photomask PM may be retained to be spaced apart from each other by a distance of several micrometers in the mask stage 110. By making a configuration as described above, when the wafer exposure process is performed in a state where the photomask PM is fixed to the first fixing portion 114 of the mask holder system 118 and the upper end of the pellicle assembly 120 is fixed to the second fixing portion 116 of the mask holder system 118, a path along which the foreign material existing in the mask stage 110 may move to the pattern region of the photomask PM is formed to be narrow and long, thereby efficiently preventing the pattern region of the photomask PM from being polluted.

Although the reflective photomask is described as an example in this embodiment, embodiments are not limited thereto. For example, embodiments may be applicable to a case where a photomask is fixed to a mask stage in an exposure process using a transparent photomask, e.g., in an exposure process using a KrF excimer laser (248 nm), an ArF excimer laser (193 nm), or a fluoride (F2) excimer laser (157 nm).

FIG. 8 is a schematic cross-sectional view illustrating an exemplary configuration of a photomask carrier 380, which may be used instead of the photomask carrier 180 of FIG. 1, in a semiconductor device manufacturing apparatus according to embodiments. In FIG. 8, reference numerals that are the same as those of FIG. 5 denote the same components, and thus descriptions thereof will not be repeated here.

Referring to FIG. 8, the photomask carrier 380 may be used to protect the photomask PM in a path along which the photomask PM having a plurality of pattern elements P220 formed in a pattern region P210 is provided to the mask stage 110 (see FIG. 1). The photomask carrier 380 may include an inner pod 340 and the outer pod 260.

The inner pod 340 may include a base plate 342 that faces a first surface S1 of the photomask PM, having the pattern region P210 in which the plurality of pattern elements P220 are formed, and a cover 244 that receives the photomask PM in conjunction with the base plate 342. A recessed mounting surface 342R, in which the pellicle assembly 120 may be mounted, is formed in an approximately central portion of the base plate 342. In an approximately central portion of the recessed mounting surface 234R, there is formed a base hole 342H that exposes the pattern region P210 and a peripheral region thereof through the pellicle membrane 124 at a position corresponding to the pattern region P210 of the photomask PM in which the plurality of pattern elements P220 are formed. The base hole 342H may be disposed at an approximately central portion of the base plate 342.

The base plate 342 may include a base connection portion 342C. The base connection portion 342C may be directly connected to the second fixing portion 116 (see FIG. 1) of the mask holder system 118 in a state where the pellicle assembly 120 is received on the recessed mounting surface 342R.

In some embodiments, the pellicle assembly 120 may be fixed onto the recessed mounting surface 342R in an adhesive manner. In some embodiments, the pellicle assembly 120 may be supported on the recessed mounting surface 342R without a separate fixing member because the recessed mounting surface 342R functions as a supporting surface.

The photomask carrier 380 provides the space that receives the pellicle assembly 120 inside the inner pod 340, allowing the photomask PM to be transferred while being protected by the pellicle assembly 120. In addition, the photomask PM and the pellicle assembly 120 are doubly protected by the inner pod 340 and the outer pod 260, maintaining sealability of the space in which the photomask PM is received.

The pellicle assembly 120 received within the inner pod 340 may be disposed apart from the photomask PM. In some embodiments, when the photomask PM is received within the inner pod 340, the pellicle assembly 120 and the photomask PM may be retained to be spaced apart from each other by a distance of several micrometers. As described above, the distance between the pellicle assembly 120 and the photomask PM may be retained as it is when the photomask PM and the pellicle assembly 120 are fixed to the mask stage 110 (see FIG. 1).

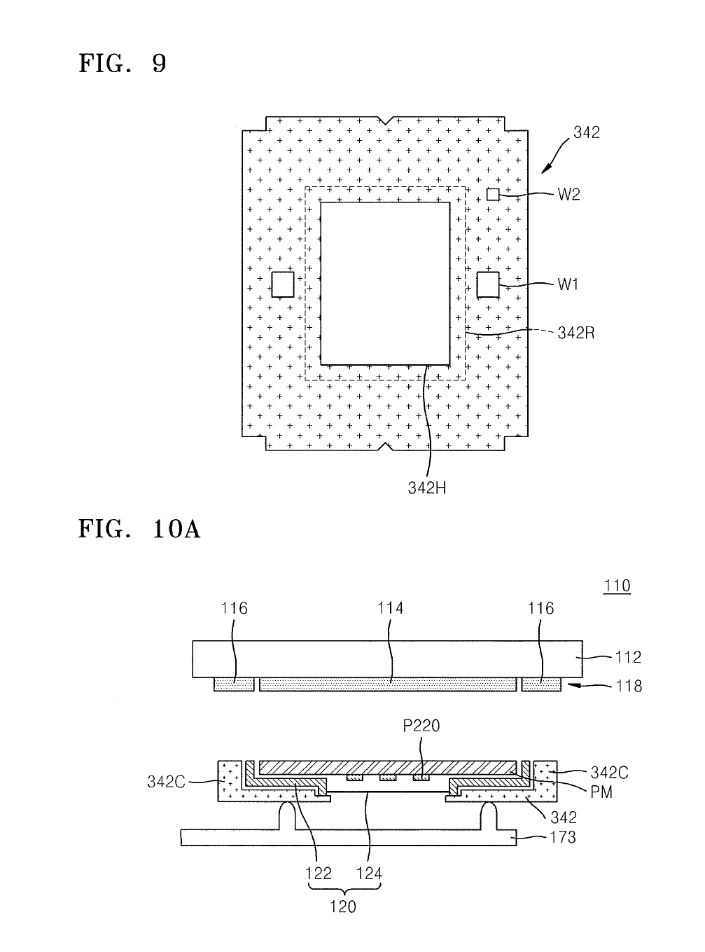

FIG. 9 is a bottom view illustrating the base plate 342 included in the inner pod 340 of the photomask carrier 380 of FIG. 8. In FIG. 9, reference numerals that are the same as those of FIG. 6 denote the same components, and thus detailed descriptions thereof will not be repeated here.

As illustrated in FIG. 9, the base hole 342H may be formed in an approximately central portion of the base plate 342. The base hole 342H is surrounded by the recessed mounting surface 342R and is disposed corresponding to the pattern region P210 of the photomask PM and its peripheral region.

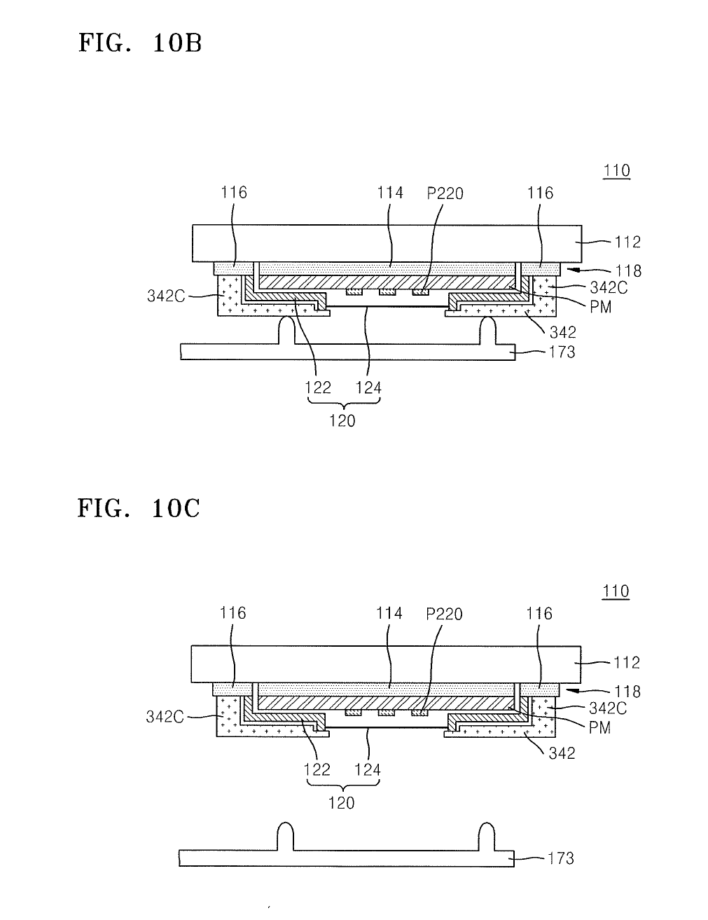

FIGS. 10A to 10C are schematic cross-sectional views illustrating stages in a process of fixing the photomask PM to the mask stage 110 in a case of storing and transferring the photomask PM using the photomask carrier 380 of FIG. 8.

Referring to FIG. 10A, the base plate 342 is transferred to the mask stage 110 by the carrying hand 173 in a state in which the photomask PM is received in the base plate 342 of the inner pod 340 (see FIG. 8) according to a similar process to the process as described with reference to FIG. 7A. That is, in the state in which the front side of the photomask PM, in which the plurality of pattern elements P220 are formed, is covered by the pellicle assembly 120 and the base plate 342, the base plate 342 that receives the photomask PM is supported by the carrying hand 173, and the photomask PM is transferred to the mask stage 110 in a state where the movement of the photomask PM is controlled by the carrying hand 173.

As illustrated in FIG. 10A, the photomask PM is positioned to be aligned with the first fixing portion 114 under the first fixing portion 114 of the mask holder system 118. The upper end of the pellicle assembly 120 and the upper end of the base plate 342 are positioned to be aligned with the second fixing portion 116 under the second fixing portion 116 of the mask holder system 118.

Referring to FIG. 10B, the base plate 342, in which the photomask PM is received, is moved using the carrying hand 173, and the photomask PM is fixed to the first fixing portion 114 of the mask holder system 118. The upper end of the pellicle assembly 120 and the upper end of the base plate 342 are respectively fixed to the second fixing portion 116 of the mask holder system 118.

The second fixing portion 116 of the mask holder system 118 may include a base fixing region, which may be connectable to the base connection portion 342C of the base station 342, and a pellicle fixing region that may be connectable to the upper end of the pellicle assembly 120. The base fixing region and the pellicle fixing region of the second fixing portion 116 may be partial portions of a surface that faces the upper end of the pellicle assembly 120 and the upper end of the base plate 342 among an exposed surface of the second fixing portion 116.

The base connection portion 342C of the base plate 342 may be fixed to the second fixing portion 116 of the mask holder system 118, e.g., in a chucking manner, in a mechanical coupling manner, or in an adhesive manner.

Referring to FIG. 10C, in a state where the photomask PM is fixed to the first fixing portion 114 of the mask holder system 118, and the upper end of the pellicle assembly 120 and the upper end of the base plate 342 are respectively fixed to the second fixing portion 116 of the mask holder system 118, the carrying hand 173 is separated from the base plate 342. That is, as illustrated in FIG. 10C, the carrying hand 173 is separated from the base plate 342, while the base plate 342 remains attached to the second fixing portion 116 and to an end of the pellicle assembly 120. Thereafter, in the state where the photomask PM is covered by the pellicle assembly 120 and the base plate 342, a wafer exposure process may be performed.

As described with reference to FIGS. 10A to 10C, the photomask PM is received within the inner pod 340 and is transferred to the mask stage 110 in a state where the front side of the photomask PM, on which the plurality of pattern elements P220 are formed, is covered by the pellicle assembly 120, thereby preventing the pattern region of the photomask PM from being exposed to the outside. Therefore, a possibility of pollution of the photomask PM may be reduced and reliability of the exposure process may be improved.

FIG. 11 is a schematic cross-sectional view illustrating an exemplary configuration of a photomask carrier 480, which may be used instead of the photomask carrier 180 of FIG. 1, in a semiconductor device manufacturing apparatus according to embodiments. In FIG. 11, reference numerals that are the same as those of FIGS. 5 to 10 denote the same components, and descriptions thereof will not be repeated here.

Referring to FIG. 11, a pellicle assembly 420 received within an inner pod 340 of the photomask carrier 480 may include a pellicle frame 422 and a pellicle membrane 124 that is fixed to the pellicle frame 422 to define a pellicle space PS, in which the photomask is received in conjunction with the pellicle frame 422. In some embodiments, the pellicle assembly 420 may be fixed onto the recessed mounting surface 342R of the inner pod 340 in an adhesive manner. In some embodiments, the pellicle assembly 420 may be supported on the recessed mounting surface 342R without a separate fixing member because the recessed mounting surface 342R functions as a supporting surface.

The pellicle assembly 420 has an approximately similar configuration to that of the pellicle assembly 120 described with reference to FIG. 5. The pellicle frame 422 of the pellicle assembly 420 may have a structure that covers the front side of the photomask PM, in which the pattern region P210 is formed, but does not cover the other sides of the photomask PM. For example, as illustrated in FIG. 11, the pellicle frame 422 of the pellicle assembly 420 may extend only along the front side of the photomask PM, i.e., without extending along a lateral side of the photomask PM.

The pellicle assembly 420 received within the inner pod 340 may be disposed apart from the photomask PM. In some embodiments, when the photomask PM is received within the inner pod 340, the pellicle assembly 420 and the photomask PM may be retained to be spaced apart from each other by a distance of several micrometers. As described above, the distance between the pellicle assembly 420 and the photomask PM may be retained as it is when the photomask PM and the pellicle assembly 420 are fixed to the mask stage 110 (see FIG. 1).

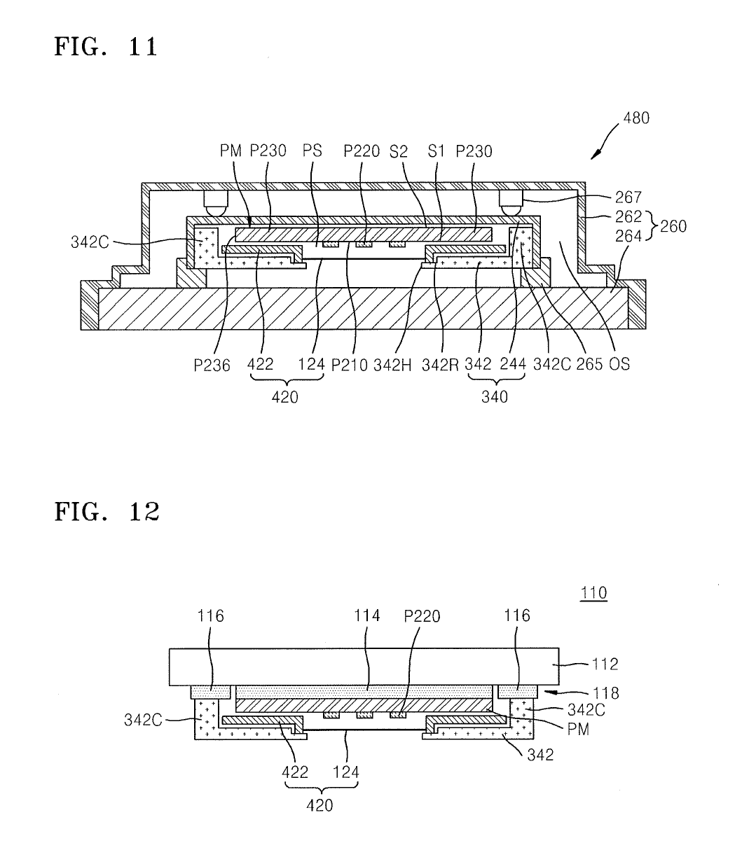

FIG. 12 is a diagram illustrating a state in which the photomask PM, the pellicle assembly 420, and the base plate 342 are fixed to the mask holder system 118 in the mask stage 110.

According to a process similar to the process as described with reference to FIGS. 10A to 10C, the photomask PM may be fixed to the first fixing portion 114 of the mask holder system 118, and the upper end of the base plate 342 may be fixed to the second fixing portion 116 of the mask holder system 118. Unlike the stage illustrated in FIG. 10C, the base plate 342 of the inner pod 340 (see FIG. 12) is connected to the second fixing portion 116 of the mask holder system 118, whereas the pellicle assembly 420 is spaced apart from the second fixing portion 116 in a state of being retained by the base plate 342 in FIG. 12. That is, the pellicle assembly 420 is connected indirectly to the second fixing portion 116 of the mask holder system 118 through the base plate 342.

In the mask stage 110 of FIG. 12, a wafer exposure process may be performed in the state where the photomask PM is covered by the pellicle assembly 420 and the base plate 342. As described with reference to FIGS. 11 and 12, the photomask PM is received within the inner pod 340 and is transferred to the mask stage 110 in a state where the front side of the photomask PM, on which the plurality of pattern elements P220 are formed, is covered by the pellicle assembly 420, thereby preventing the pattern region of the photomask PM from being exposed to the outside. Therefore, a possibility of pollution of the photomask PM may be reduced and reliability of the exposure process may be improved.

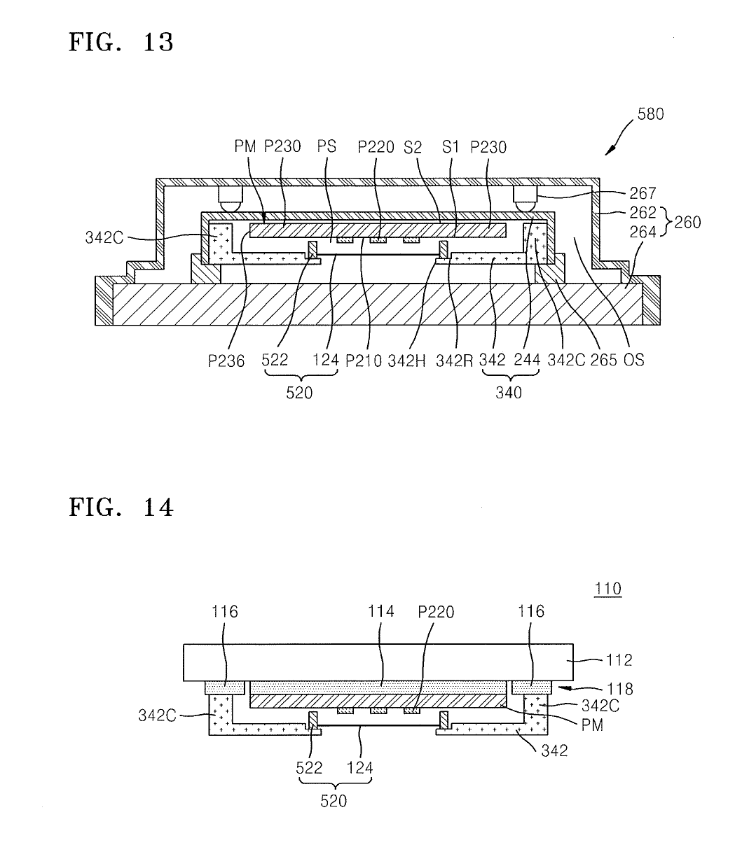

FIG. 13 is a schematic cross-sectional view illustrating an exemplary configuration of a photomask carrier 580, which may be used instead of the photomask carrier 180 of FIG. 1, in a semiconductor device manufacturing apparatus according to embodiments. In FIG. 13, reference numerals that are the same as those of FIGS. 5 to 12 denote the same components, and thus descriptions thereof will not be repeated here.

Referring to FIG. 13, a pellicle assembly 520 received within the inner pod 340 of the photomask carrier 580 may include a pellicle frame 522 and a pellicle membrane 124 that is fixed to the pellicle frame 522 to define a pellicle space PS in which the photomask is received in conjunction with the pellicle frame 522. In some embodiments, the pellicle assembly 520 may be fixed onto the recessed mounting surface 342R of the inner pod 340 in an adhesive manner. In some embodiments, the pellicle assembly 520 may be supported on the recessed mounting surface 342R without a separate fixing member because the recessed mounting surface 342R functions as a supporting surface.

The pellicle assembly 520 has an approximately similar configuration to that of the pellicle assembly 120 as described with reference to FIG. 5. The pellicle assembly 520 may has a width within the area of the recessed mounting surface 342R. An end of the pellicle frame 522 of the pellicle assembly 520 faces the photomask PM at a position spaced apart from the front side of the photomask PM in which the pattern region P210 are formed.

The pellicle assembly 520 received within the inner pod 340 may be disposed apart from the photomask PM. In some embodiments, when the photomask PM is received within the inner pod 340, the end of the pellicle assembly 520 and the photomask PM may be retained to be spaced apart from each other by a distance of several micrometers. For example, as illustrated in FIG. 13, the pellicle frame 522 of the pellicle assembly 520 may have a linear cross-section extending vertically from the base plate 342 toward the photomask PM and spaced apart therefrom.

FIG. 14 is a diagram illustrating a state in which the photomask PM, the pellicle assembly 520, and the base plate 342 are fixed to the mask holder system 118 in the mask stage 110.

According to a process similar to the process as described with reference to FIGS. 10A to 10C, the photomask PM may be fixed to the first fixing portion 114 of the mask holder system 118, and the upper end of the base plate 342 may be fixed to the second fixing portion 116 of the mask holder system 118.

Unlike the stage illustrated in FIG. 10C, the base plate 342 of the inner pod 340 (see FIG. 14) is connected to the second fixing portion 116 of the mask holder system 118, whereas the pellicle assembly 520 is spaced apart from the second fixing portion 116 while being retained by the base plate 342 in FIG. 14. That is, the pellicle assembly 520 is connected indirectly to the second fixing portion 116 of the mask holder system 118 through the base plate 342. In the mask stage 110 of FIG. 14, a wafer exposure process may be performed in the state where the photomask PM is covered by the pellicle assembly 520 and the base plate 342.

As described with reference to FIGS. 13 and 14, the photomask PM is received within the inner pod 340 and is transferred to the mask stage 110 in a state where the front side of the photomask PM on which the plurality of pattern elements P220 are formed is covered by the pellicle assembly 520, thus preventing the pattern region of the photomask PM from being exposed to the outside. Therefore, a possibility of pollution of the photomask PM may be reduced and reliability of the exposure process may be improved.

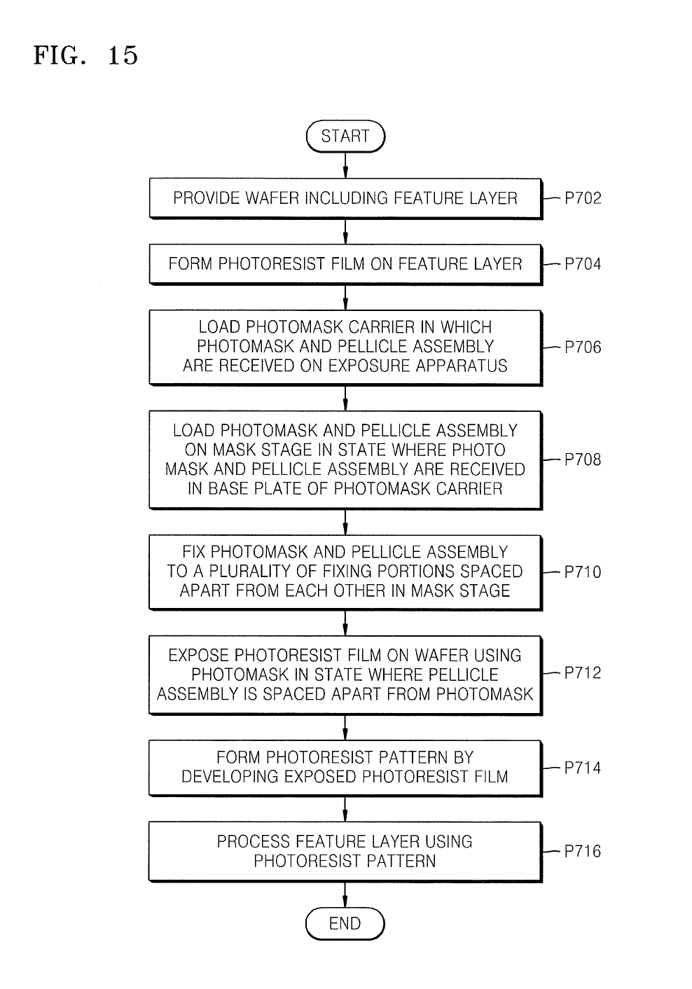

FIG. 15 is a flowchart illustrating a method of manufacturing a semiconductor device according to some embodiments.

Referring to FIG. 15, in operation P702, a wafer including a feature layer is provided. In some embodiments, the feature layer may be a conductive layer or an insulating layer formed on the wafer. For example, the feature layer may be formed of a metal, a semiconductor, or an insulating material. In some embodiments, the feature layer may be a portion of the wafer.

In operation P704, a photoresist film is formed on the feature layer. In some embodiments, the photoresist film may be formed of resist material for EUV exposure (wavelength 13.5 nm). In some embodiments, the photoresist film may be formed of a resist for a F₂ excimer laser (157 nm), a resist for an ArF excimer laser (193 nm), or a resist for a KrF excimer laser (248 nm). The photoresist film may be formed of a positive type photoresist or a negative type photoresist.

In some embodiments, a photoresist composition including photosensitive polymers having acid-labile groups, potential acid, and a solvent may be coated on the feature layer to form a photoresist film formed of the positive type photoresist.

In some embodiments, the photosensitive polymer may be a (meth)acrylate-based polymer. The (meth)acrylate-based polymer may be an aliphatic (meth)acrylate-based polymer. For example, the photosensitive polymer may be polymethylmethacrylate (PMMA), poly(t-butylmethacrylate), poly(methacrylic acid), poly(norbornylmethacrylate), di-copolymer or tri-copolymer of repeating units of the (meth)acrylate-based polymers, and mixtures thereof. The photosensitive polymers may be substituted with acid-labile protecting groups. The protecting groups may include tert-butoxycarbonyl, t-BOC, tetrahydropyranyl, trimethylsilyl, phenoxyethyl, cyclohexenyl, tert-butoxycarbonylmethyl, tert-butyl, adamantyl, or norbornyl groups. However, embodiments are not limited thereto.

In some embodiments, the potential acid may include a photoacid generator (PAG), a thermoacid generator (TAG), or a combination thereof. In some embodiments, the PAG may be formed of material that generates acid when exposed to light selected from EUV light (1 to 31 nm), a F₂ excimer laser (157 nm), an ArF excimer laser (193 nm), and a KrF excimer laser (248 nm). The PAG may include onium salt, a halogen compound, nitrobenzyl esters, alkyl sulfonates, diazonaphthoquinones, amino sulfonates, disulfonates, diazomethans, and sulfoxy ketones.

In operation P706 of FIG. 15, a photomask carrier in which a photomask and a pellicle assembly are received together is loaded onto an exposure apparatus. In some embodiments, the photomask may be the photomask PM as described with reference to FIG. 2B. In some embodiments, the pellicle assembly may be the pellicle assembly 120 as described with reference to FIGS. 1, 3A to 3C, 5, and 7A to 7C. In some embodiments, the photomask carrier may be the photomask carrier 280 as described with reference to FIG. 5. The photomask carrier in which the photomask and the pellicle assembly are received together may be loaded on the mask load port 100G of the semiconductor device manufacturing apparatus 100 of FIG. 1.

In operation P708 of FIG. 15, the photomask and the pellicle assembly are loaded onto the mask stage in a state in which the photomask and the pellicle assembly are received together in the base plate of the photomask carrier. In some embodiments, the base plate of the photomask carrier may be the base plate 242 of the photomask carrier 280 as described with reference to FIG. 5. In some embodiments, the mask stage may be the mask stage 110 of the semiconductor device manufacturing apparatus 100 of FIG. 1.

In operation P710, the photomask and the pellicle assembly are fixed to a plurality of fixing portions spaced apart from one another on the mask stage. In some embodiments, the plurality of fixing portions that are spaced apart from each other may be the first fixing portion 114A and the second fixing portion 116A of FIG. 2A, or the first fixing portion 114A and the plurality of second fixing portion 116B of FIG. 4A. The photomask and the pellicle assembly may be fixed to the plurality of fixing portions spaced apart from each other on the mask stage using one of the methods as described with reference to FIGS. 3A to 3C, but embodiments are not limited thereto.

In operation P712, the photoresist film on the wafer is exposed using the photomask in a state in which the pellicle assembly is spaced apart from the photomask. In some embodiments, the exposure process may be performed by a reflective exposure system, but embodiments are not limited thereto, e.g., a transparent exposure system may be used.

In operation P714, photoresist patterns may be formed by developing the exposed photoresist film.

In operation P716, the feature layer is processed using the photoresist patterns. In some embodiments, the feature layer is etched using the photoresist patterns as an etching mask to form fine feature patterns for processing of the feature layer according to operation P716. In some embodiments, impurity ions may be implanted in the feature layer by using the photoresist patterns as an ion implantation mask for processing of the feature layer according to operation P716. In some embodiments, a separate process film may be formed on the feature layer exposed through the photoresist patterns formed in operation P714 for processing the feature layer according to operation P716. The process film may include a conductive film, an insulating film, a semiconductor film, or a combination thereof.

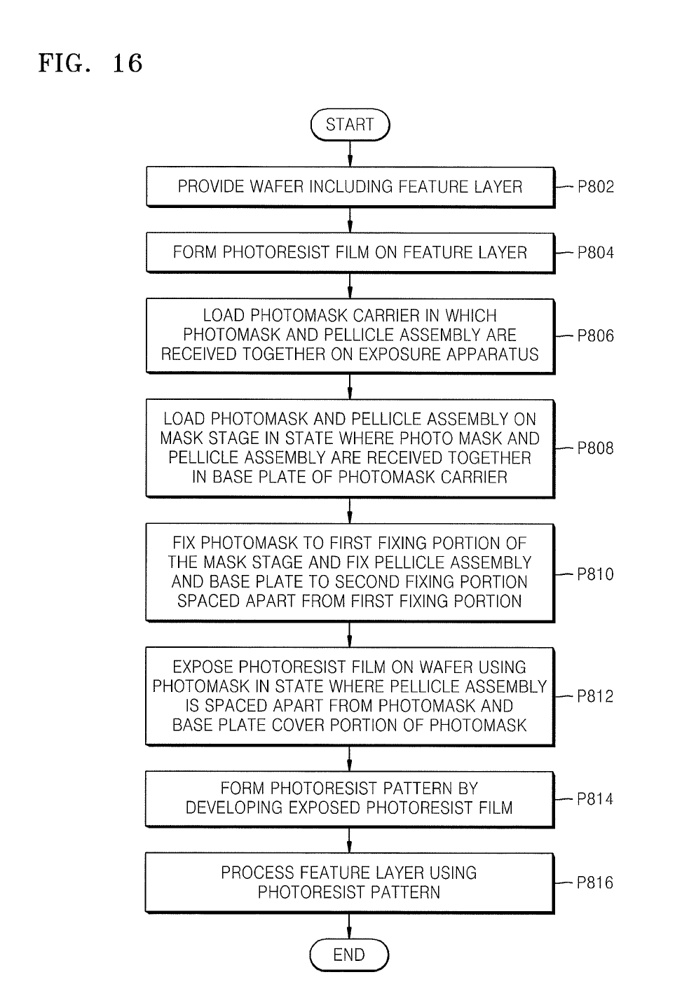

FIG. 16 is a flowchart illustrating a method of manufacturing a semiconductor device according to embodiments.

Operations P802, P804, P806, and P808 are sequentially performed similarly to operations P702, P704, P706, and P708 described with reference to FIG. 15. The base plate of the photomask carrier used in operations P806 and P808 of FIG. 16 may be the base plate 342 included in any one of the photomask carriers 380, 480 and 580 as respectively described with reference to FIGS. 8, 11 and 13. The pellicle assembly used in operations P806 and P808 of FIG. 16 may be any one of the pellicle assemblies 120, 420 and 520 as respectively described with reference to FIGS. 8, 11 and 13.

In operation P810, the photomask is fixed to the first fixing portion of the mask stage and the pellicle assembly and the base plate are fixed to the second fixing portion spaced apart from the first fixing portion. The first fixing portion may be the first fixing portion 114A of FIGS. 2A and 4A. The second fixing portion may be the second fixing portion 116A of FIG. 2A or the plurality of second fixing portions 116B of FIG. 4A. However, embodiments are not limited thereto.

In operation 812, a photoresist film on the wafer is exposed by using the photomask in a state where the pellicle assembly is spaced apart from the photomask and the base plate covers a portion of the photomask. In some embodiments, the mask stage 110 may be retained in the state illustrated in FIG. 10C, 12 or 14 in the exposure process. The exposure process may be performed by a reflective exposure system, but embodiments are not limited thereto, e.g., a transparent exposure system may be used.

In operation P814 of FIG. 16, the exposed photoresist film is developed to form photoresist patterns, and in operation P816, the feature layer is processed by using the photoresist patterns, similar to operation P714 and P716 as described with reference to FIG. 15.

FIG. 17 is a block diagram illustrating a memory card 1200 including a semiconductor device manufactured using the semiconductor device manufacturing apparatus according to embodiments.

The memory card 1200 includes a memory controller 1220 that generates command and address signals C/A and a memory module 1210, for example, a flash memory including one or a plurality of flash memory elements. The memory controller 1220 includes a host interface 1223 that transmits and receives command and address signals to and from a host, and a memory interface 1225 that transmits and receives command and address signals to and from the memory module 1210 again. The host interface 1223, a controller 1224, and the memory interface 1225 communicate with a controller memory 1221, such as a static random access memory (SRAM), and a processor 1222, such as a central processing unit (CPU) through a common bus 1228.

The memory module 1210 receives command and address signals from the memory controller 1220, stores data in at least one of the memory elements of the memory module 1210 in response to the signals, and retrieves data from at least one of the memory elements. Each memory element includes a plurality of addressable memory cells and a decoder that generates column and row signals to access at least one of the addressable memory cells during programming and read operations.

Each component of the memory card 1200 including the memory controller 1220, the electronic elements 1221, 1222, 1223, 1224 and 1225 included in the memory controller 1220, and the memory module 1210, may include a semiconductor device manufactured using the semiconductor device manufacturing apparatus according to embodiments. In addition, each component of the memory card 1200 including the memory controller 1220, the electronic elements 1221, 1222, 1223, 1224 and 1225 included in the memory controller 1220, and the memory module 1210, may include a semiconductor device manufactured using the method of manufacturing a semiconductor device as described with reference to FIG. 15 or 16.

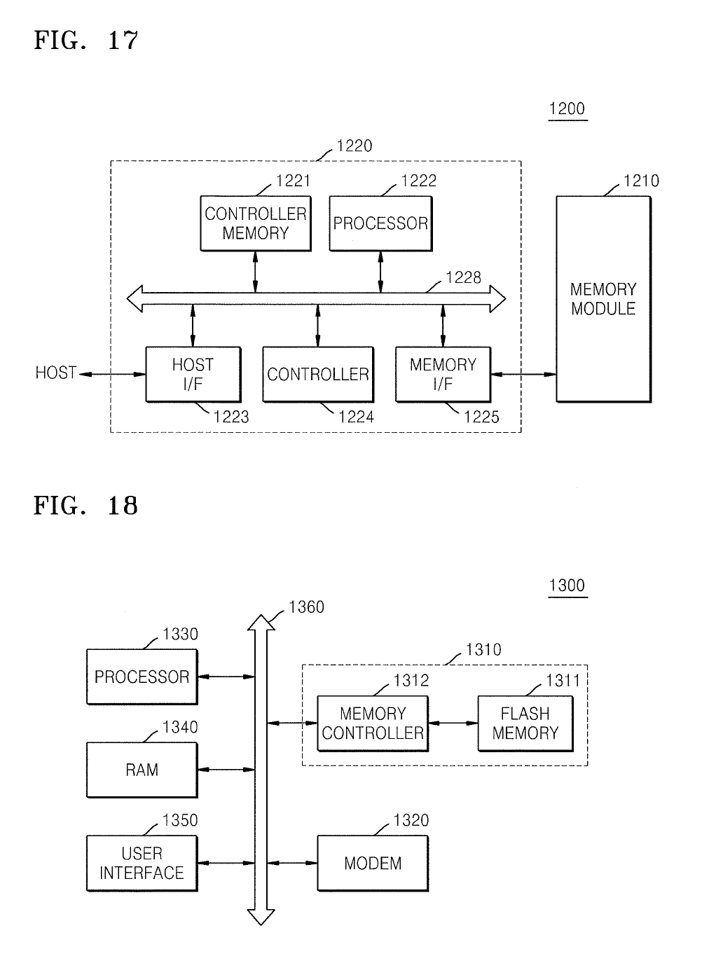

FIG. 18 is a block diagram illustrating a memory system 1300 using a memory card 1310 including a semiconductor device manufactured by using the method of manufacturing a semiconductor device according to embodiments.

The memory system 1300 may include a processor, such as a CPU, a random access memory (RAM) 1340, a user interface (UI) 1350, and a modem 1320 that communicate with each other through a common bus 1360. Each of the elements transmits a signal to the memory card 1310 and receives a signal from the memory card 1310 through the common bus 1360. Each component of the memory system 1300 including the processor 1330, the RAM 1340, the UI 1350, and the modem 1320 along with the memory card 1310 may include a semiconductor device manufactured using the semiconductor device manufacturing apparatus according to embodiments. The memory system 1300 may include a semiconductor device manufactured by using the method of manufacturing a semiconductor device as described with reference to FIG. 15 or 16.

The memory system 1300 may be applicable to various electronic application fields. For example, the memory system 1300 may be applicable to solid state drives (SSDs), complementary metal oxide semiconductor (CMOS) image sensors (CISs), and a computer application chipset.

The memory systems and the elements may be packaged in any package form among various package forms including, but not limited to, ball grid arrays (BGAs), chip scale packages (CSPs), plastic leaded chip carrier (PLCC), plastic dual in-line package (PDIP), multi chip package (MCP), wafer-level fabricated package (WFP), and wafer-level processed stack package (WSP).

By way of summation and review, when a photomask is polluted by foreign material, e.g., particles from a surrounding environment, or is deformed by a surrounding environment, a defect may occur on a wafer onto which patterns of the photomask are transcribed. Therefore, there is a need for a system that protects a photomask used in a lithography process to prevent the photomask from being polluted or being deformed due to foreign material or a surrounding environment so as to improve productivity upon manufacturing of semiconductor devices. Accordingly, embodiments provide a semiconductor device manufacturing apparatus that protects a photomask from pollution during storage, transfer, and use thereof, prevents the photomask from being deformed, and shortens a turn around time (TAT) for rework of the photomask to improve productivity.

In detail, according to embodiments, in order to minimize loss in productivity and the possibility of mask damage upon mounting/demounting of the pellicle assembly, a pellicle frame is attached to a separate carrier that protects the photomask rather than being attached to a surface of a substrate on which a pattern surface of the photomask is disposed. The pellicle frame may be attached by a temporary attachment or by a permanent attachment.

In the temporary attachment, the pellicle frame is clamped to a reticle stage during wafer exposure and to a carrier during wafer transfer for mask protection. That is, when the mask is stored and transferred, the pellicle frame is fixed to the carrier. When the mask is used for wafer exposure, the pellicle frame may be easily separated from the carrier and be clamped to the mask stage, preventing the movement of the pellicle frame along with the mask. In the permanent attachment, the pellicle frame is permanently fixed to the carrier, so the carrier is clamped to the reticle stage during wafer exposure, rather than being separated form the pellicle frame.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device manufacturing apparatus, comprising:
a mask stage including a mask holder system that fixes a photomask, the mask holder system including:
a first fixing portion mounted at a first position of the mask holder system to fix the photomask; and
a second fixing portion at a second position of the mask holder system and spaced apart from the first position, the second fixing portion fixing a pellicle assembly to be spaced apart from the photomask on the first fixing portion.

2. The semiconductor device manufacturing apparatus as claimed in claim 1, wherein each of the first and second fixing portions is an electrostatic chuck.

3. The semiconductor device manufacturing apparatus as claimed in claim 1, wherein the second fixing portion includes a connection member, the connection member mechanically connecting between the pellicle assembly and the second fixing portion.

4. The semiconductor device manufacturing apparatus as claimed in claim 1, wherein the pellicle assembly includes:
a pellicle frame with a pellicle connection portion, the pellicle connection portion being directly connectable to the second fixing portion of the mask holder system; and
a pellicle membrane fixed to the pellicle frame, a pellicle space being defined between the pellicle membrane and the photomask.

5. The semiconductor device manufacturing apparatus as claimed in claim 4, wherein the pellicle connection portion is fixed to the second fixing portion of the mask holder system via electrostatics, a mechanical member, or an adhesive.

6. The semiconductor device manufacturing apparatus as claimed in claim 1, further comprising a photomask carrier that protects the photomask, the photomask carrier having an inner pod, and the inner pod including:
a base plate facing a first surface of the photomask, the first surface of the photomask including a pattern region; and
a cover facing a second surface of the photomask opposite to the first surface, a space for the photomask being defined between the cover and the base plate.

7. The semiconductor device manufacturing apparatus as claimed in claim 6, wherein the base plate includes a recessed mounting surface to receive the pellicle assembly.

8. The semiconductor device manufacturing apparatus as claimed in claim 7, wherein the base plate further comprises a base hole surrounded by the recessed mounting surface, the base hole corresponding to the pattern region of the photomask and to a peripheral region of the pattern region.

9. The semiconductor device manufacturing apparatus as claimed in claim 8, wherein the pellicle assembly includes:
a pellicle frame receivable in the recessed mounting surface of the base plate; and
a pellicle membrane fixed to the pellicle frame, the pellicle membrane defining a pellicle space in conjunction with the pellicle frame.

10. The semiconductor device manufacturing apparatus as claimed in claim 9, wherein the base plate includes a base connection portion directly connectable to the second fixing portion of the mask holder system, in a state where the pellicle assembly is received in the recessed mounting surface.

11. The semiconductor device manufacturing apparatus as claimed in claim 10, wherein the pellicle connection portion is fixed to the second fixing portion via electrostatics, a mechanical member, or an adhesive.

12. The semiconductor device manufacturing apparatus as claimed in claim 7, wherein the pellicle assembly is fixed onto the recessed mounting surface.

13. The semiconductor device manufacturing apparatus as claimed in claim 6, wherein the photomask carrier further comprises an outer pod including a shell and a door, a sealed space for the inner pod being defined between the shell and the door.

14. A semiconductor device manufacturing apparatus, comprising:
a mask stage with a mask holder system, the mask holder system including:
a first fixing portion that fixes a photomask, and
a second fixing portion mounted at a position spaced apart from the first fixing portion to fix a pellicle assembly that protects the photomask at a position spaced apart from the photomask; and
a photomask carrier that protects the photomask in a path along which the photomask is supplied to the mask stage, the photomask carrier including:
a base plate including a recessed mounting surface to receive the pellicle assembly and a base hole, the base hole being surrounded by the recessed mounting surface and disposed corresponding to a pattern region of the photomask and a peripheral region of the pattern region, and
a cover that defines in conjunction with the base plate a space for receiving the photomask.

15. The semiconductor device manufacturing apparatus as claimed in claim 14, wherein the second fixing portion of the mask holder system includes a base fixing region that is connectable to an end of the base plate.

16. A semiconductor device manufacturing apparatus, comprising:
a mask holder system on a stage, the mask holder system including:
a first fixing portion at a first position of the stage, and
a second fixing portion at a second position of the stage, the second fixing portion being completely separated and spaced apart from the first fixing portion;
a photomask on the first fixing portion of the mask holder system; and
a pellicle assembly on the second fixing portion of the mask holder system, the pellicle assembly being spaced apart from the photomask.

17. The semiconductor device manufacturing apparatus as claimed in claim 16, wherein the photomask contacts only the first fixing portion among the first and second fixing portions, and the pellicle assembly contacts only the second fixing portion among the first and second fixing portions.

18. The semiconductor device manufacturing apparatus as claimed in claim 16, further comprising a photomask carrier surrounding the photomask and the pellicle assembly, the photomask carrier including:
a base plate including a recessed mounting surface, the pellicle assembly being positioned in the recessed mounting surface; and
a cover defining a space between the cover and the base plate, the photomask and the pellicle assembly being positioned in the defined space.

19. The semiconductor device manufacturing apparatus as claimed in claim 18, wherein the photomask carrier is separable from the stage, the pellicle assembly being an outermost element on the stage.

20. The semiconductor device manufacturing apparatus as claimed in claim 18, wherein the cover overlaps the pellicle frame and is directly attached to the second fixing portion of the mask holder system, the cover being an outermost element on the stage.
